(19) United States
(12) Patent Application Publication
(10) Pub. No.: US 2007/0187799 A1
(43) Pub. Date: Aug. 16, 2007

(54) Semiconductor device and method of manufacturing the same

(76) Inventors: Toshiharu Tanaka, Tokyo (JP); Shinya Watanabe, Tokyo (JP); Mutsumi Okajima, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/412,044

(22) Filed: Apr. 27, 2006

(30) Foreign Application Priority Data
Feb. 16, 2006 (JP) 2006-39368

(51) Int. Cl. H01L 29/00

(52) U.S. Cl. 257/510; 257/E27.084

(57) ABSTRACT

A method of manufacturing a semiconductor device according to an aspect of the present invention comprises: depositing an insulation film on a silicon substrate; forming element isolation regions by processing the insulation film as well as exposing the surface of the silicon substrate in the region thereof acting as active element forming regions later; and forming the active element forming regions by epitaxially growing a silicon film on the exposed surface of the silicon substrate such that the thickness thereof is larger than the short side width in the perpendicular cross section thereof as well as smaller than the dimension of the element isolation regions in the depth direction thereof.

### CROSS-REFERENCE TO RELATED APPLICATION

This application is based upon and claims the benefit of priority from prior Japanese Patent Application No. 2006-39368 filed on Feb. 16, 2006; the entire contents of which are incorporated herein by reference.

### BACKGROUND OF THE INVENTION

1. Field of the Invention

The present invention relates to a semiconductor device and a method of manufacturing the same, and more particularly to the structure of an active element forming region and an element isolation region of a semiconductor device such as a semiconductor storage device and to a process for forming these regions.

2. Related Background Art

In a conventional technology of a semiconductor device such as a semiconductor storage device, when an active element forming region and element isolation regions are formed to separate adjacent elements from each other, a trench is formed by etching a silicon substrate, and the trench is flattened by being filled with an insulation film of, for example, a silicon oxide film and the like to thereby form the element isolation regions of an STI (Shallow Trench Isolation) structure, and the region between the element isolation regions is used as the active element forming region (Active Area).

However, when elements are more miniaturized hereinafter, there is a possibility that the structure of the insulation-film-buried structure in the trench of the STI structure is deteriorated in quality because the ratio of vertical/horizontal dimensions of the section of the element isolation regions of the STI structure, that is, the aspect ratio thereof increases.

Accordingly, there is required a countermeasure that can prevent or suppress deterioration of quality of the insulation-film-buried structure even if the aspect ratio increases.

As to this point, heretofore, proposals are made to improve the structure as disclosed in, for example, Japanese Patent Laid-Open Publication No. 2004-266291.

However, it is contemplated that the structure can be further improved or can be improved from a different point of view.

### SUMMARY OF THE INVENTION

According to an aspect of a semiconductor device of the present invention, there is provided a semiconductor device comprising:

a silicon substrate;

element isolation regions formed by processing an insulation film deposited on the silicon substrate; and

active element forming regions composed of a silicon film having a thickness, which is larger than the short side width in the perpendicular cross section thereof as well as smaller than the dimension of the element isolation regions in the depth direction thereof, and having a surface orientation (111) appearing on the upper surface thereof, and formed between one element isolation region and the other element isolation region.

According to an aspect of a method of manufacturing a semiconductor device of the present invention, there is provided a method of manufacturing a semiconductor device comprising:

depositing an insulation film on a silicon substrate;

forming element isolation regions by processing the insulation film as well as exposing the surface of the silicon substrate in the region thereof acting as active element forming regions later; and

forming the active element forming regions by epitaxially growing a silicon film on the exposed surface of the silicon substrate such that the thickness thereof is larger than the short side width in the perpendicular cross section thereof as well as smaller than the dimension of the element isolation regions in the depth direction thereof.

### BRIEF DESCRIPTION OF THE DRAWINGS

FIGS. 1A and 1B to FIGS. 4A and 4B are sectional views showing sectional structures in a direction perpendicular to a bit line and in a direction perpendicular to a word line of a semiconductor storage device according to a first embodiment of the present invention at respective steps of the manufacturing method thereof.

FIGS. 5A and 5B to FIGS. 7A and 7B are sectional views showing sectional structures in a direction perpendicular to a bit line and in a direction perpendicular to a word line of a semiconductor storage device according to a second embodiment of the present invention at respective steps of the manufacturing method thereof.

FIG. 8 is a sectional view showing the sectional structure in a direction perpendicular to a bit line of the semiconductor storage device according to a third embodiment of the present invention.

FIG. 9 is a sectional view showing the sectional structure in a direction perpendicular to a bit line of the semiconductor storage device according to a fourth embodiment of the present invention.

### DETAILED DESCRIPTION OF THE EMBODIMENTS

A semiconductor device and a method of manufacturing the same will be described below in detail with reference to the drawings. Although a semiconductor storage device will be described as an example of the semiconductor device in the following embodiments, the present invention can be applied to any type of semiconductor devices such as a logic semiconductor device and the like.

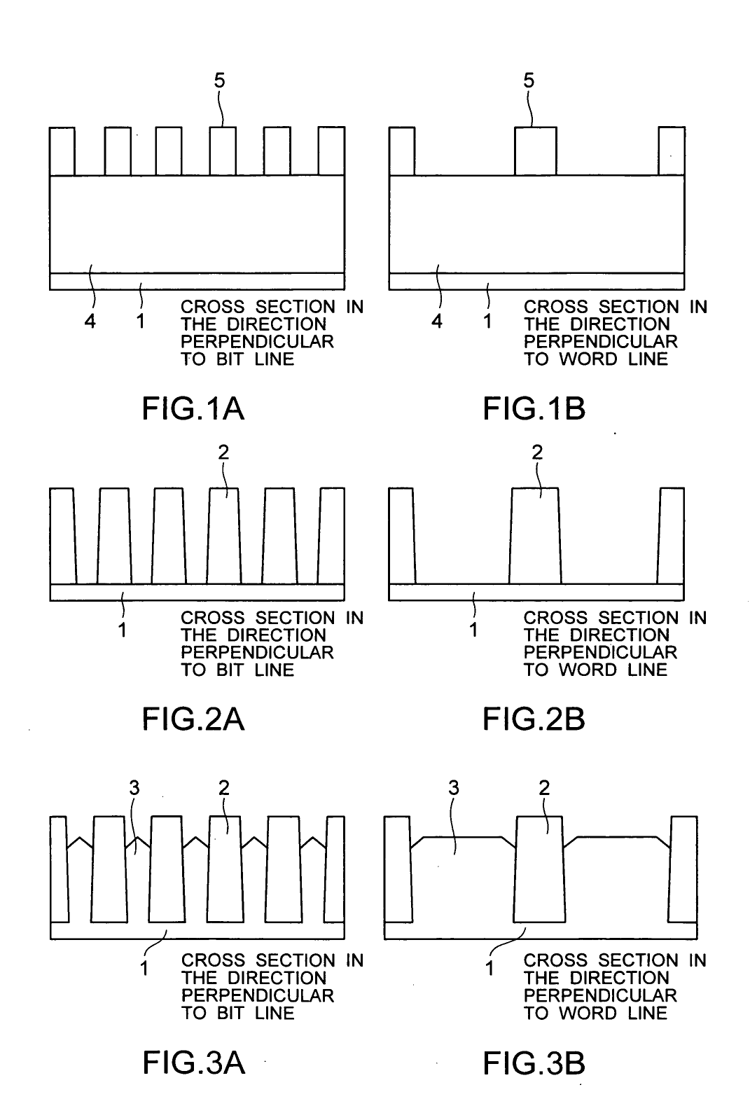

FIGS. 1A and 1B to FIGS. 4A and 4B are sectional views showing sectional structures of a semiconductor storage device according to a first embodiment of the present invention at respective steps of the manufacturing method thereof. Note that FIGS. 1A, 2A, 3A, 4A are sectional views in a direction perpendicular to a bit line, and FIGS. 1B, 2B, 3B, 4B are sectional views in a direction perpendicular to a word line. Further, FIGS. 4A and 4B are sectional views showing sectional structures of the semiconductor storage device according to the first embodiment of the present invention when it is completed.

As shown in FIGS. 1A and 1B, in the manufacturing method of the semiconductor storage device according to the first embodiment, an insulation film 4 of, for example, an silicon oxide film and the like is deposited to an appropriate thickness on a silicon substrate 1 so that it constitutes element isolation regions later, and photoresists 5 with a predetermined pattern are formed on the insulation film 4 by photolithography.

After the photoresists 5 are formed, the photoresists 5 and the insulation film 4, which is located in the region acting as active element forming regions later, are subjected to anisotropic etching as shown in FIGS. 2A and 2B, thereby the surface of the silicon substrate 1 in the active element forming regions is exposed, and the insulation film 4 acting as STI element isolation regions 2 remains.

The photoresists 5 remaining after the anisotropic etching are removed.

Thereafter, as shown in FIGS. 3A and 3B, a silicon film is epitaxially grown on the exposed surface of the silicon substrate 1 in the active element forming regions to thereby form the active element forming regions 3.

At the time, it is important that the grown thickness of the silicon film be larger than the short side width of the active element forming regions 3 as well as smaller than the etched depth of the insulation film 4.

A reason why the grown thickness of the silicon film is made larger than the shot side width of the active element forming regions 3 is to further grow the surface of the silicon film, which begins to grow with irregular concave/convex shape, and to integrate the surface into a single chevron-like shape with a surface orientation (111). That is, it is intended to prevent a plurality of elements from being operated unevenly by the irregular concave/convex shape remaining on the surface of the silicon film.

Since the chevron-like portions on the upper surface of the silicon film that act as the active element forming regions 3 have a shape in which the surface orientation (111) appears, they have a polyhedral shape.

Further, a reason why the grown thickness of the silicon film is made smaller than the etched depth of the insulation film 4 is to prevent a disadvantage in structure and operation. That is, when the grown thickness of the silicon film is made excessively thick, the silicon films in the adjacent active element forming regions 3 are coupled with each other and further a cavity is formed in the coupling portion thereof.

After the active element forming regions 3 are formed by epitaxially growing the silicon film, the insulation film 4 is etched back by an appropriate thickness as necessary to thereby form the STI element isolation regions 2 in a predetermined shape as shown in FIGS. 4A and 4B.

With the series of steps described above, there is completed the basic structure of a memory cell portion of the semiconductor storage device according to the first embodiment of the present invention having the STI element isolation regions 2 composed of the insulation film and the active element forming regions 3 composed of the silicon film having the surface orientation (111) on the surface thereof.

The structure of the peripheral portion of the memory cell portion may be simultaneously formed at the respective steps described above or may be formed using the same insulation film burying process as a conventional process after the series of steps are executed.

Thereafter, the semiconductor storage device is completed by forming a predetermined structure likewise a conventional structure as necessary.

As described above, no insulation film burying process is used to form the STI element isolation regions 2 in the semiconductor storage device and the method of manufacturing the same according to the first embodiment of the present invention. As a result, a reliable structure with excellent quality can be formed regardless that the STI structure element isolation regions have a high aspect ratio.

Further, in the semiconductor storage device and the method of manufacturing the same according to the first embodiment of the present invention, the active element forming regions 3 are formed by epitaxially growing the silicon film on the silicon substrate 1 exposed by the anisotropic etching. Thus, the surface orientation (111) appears on the surface of the silicon film that forms the active element forming regions 3.

Therefore, it can be easily discriminated whether or not the structure of a semiconductor device is the same as the structure according to the semiconductor storage device and the method of manufacturing the same according to the first embodiment of the present invention.

Further, in the structure according to the semiconductor storage device and the method of manufacturing the same according to the first embodiment of the present invention, since the surface of the silicon film that forms the active element forming regions 3 has the chevron-like shape with the surface orientation (111), the active element forming regions 3 have a surface area larger than the conventional structure. Accordingly, a gate width W, which corresponds to the surface portion of the active element forming region 3 in a cross section perpendicular to a bit line shown in FIG. 4A is increased, thereby the amount of drive current of an element can be increased than the conventional structure.

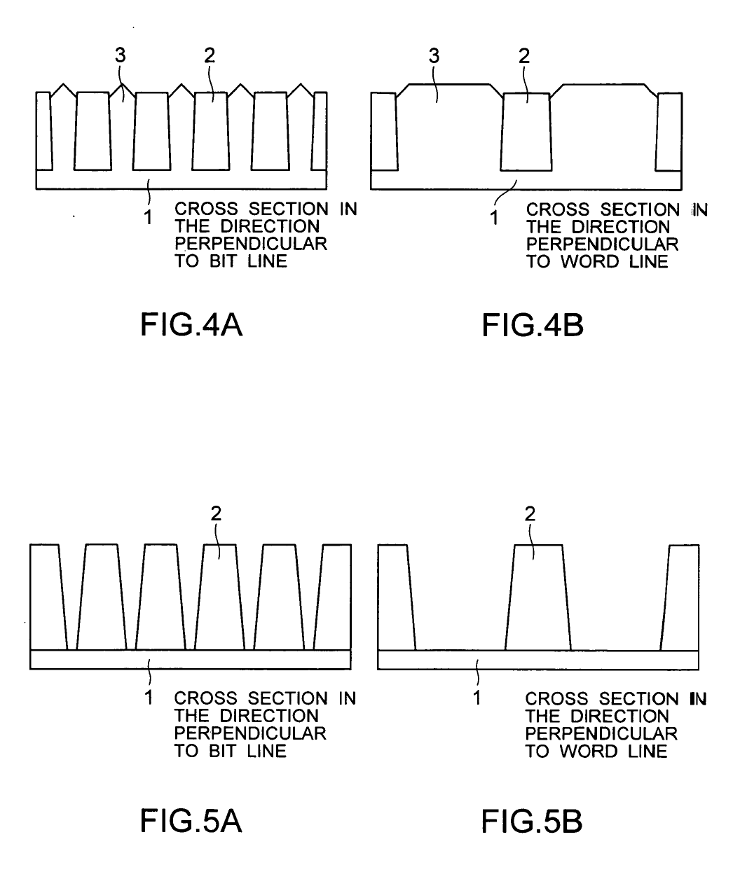

FIGS. 5A and 5B to FIGS. 7A and 7B are sectional views showing sectional structures of a semiconductor storage device according to a second embodiment of the present invention at respective steps of the manufacturing method thereof. Note that FIGS. 5A, 6A, 7A are sectional views in a direction perpendicular to a bit line, and FIGS. 5B, 6B, 7B are sectional views in a direction perpendicular to a word line. Further, FIGS. 7A and 7B are sectional views showing sectional structures of the semiconductor storage device according to the second embodiment of the present invention when it is completed.

The steps of the method of manufacturing the semiconductor storage device according to a second embodiment of the present invention are the same as those of the first embodiment up to the step at which the surface of a silicon substrate 1 in the region that acts as active element forming regions later is exposed by subjecting an insulation film 4 deposited on the silicon substrate 1 to anisotropic etching.

However, in the method of manufacturing the semiconductor storage device according to the second embodiment of the present invention, as shown in FIGS. 5A and 5B, the insulation film 4 that remains as STI element isolation regions 2 is etched such that it is formed to a forward taper shape as compared with the insulation film 4 of the first embodiment.

Thereafter, the insulation film 4 (STI element isolation regions 2) with the forward taper shape is processed by being further subjected to isotropic etching, thereby spaces acting as the active element forming regions later are increased between the STI element isolation regions 2 as shown in FIGS. 6A and 6B. That is, the spaces in which the silicon film is epitaxially grown at a subsequent step is increased.

Thereafter, as shown in FIGS. 7A and 7B, a silicon film is epitaxially grown on the exposed surface of the silicon substrate 1 in the active element forming regions to thereby form the active element forming regions 3.

At the time, as well as the first embodiment of the present invention, it is important that the grown thickness of the silicon film be larger than the short side width of the active element forming regions 3 while smaller than the etched depth of the insulation film 4.

With the series of steps described above, there is completed the basic structure of a memory cell portion of the semiconductor storage device according to the second embodiment of the present invention having the STI element isolation regions 2 composed of the insulation film and the active element forming regions 3 composed of the silicon film having the surface orientation (111) on the surface thereof.

The structure of the peripheral portion of the memory cell portion may be simultaneously formed at the respective steps described above or may be formed using the same insulation film burying process as a conventional process after the series of steps are executed.

Thereafter, the semiconductor storage device is completed by forming a predetermined structure likewise a conventional structure as necessary.

As described above, no insulation film burying process is used to form the STI element isolation regions 2 also in the semiconductor storage device and the method of manufacturing the same according to the second embodiment of the present invention. As a result, a reliable structure with excellent quality can be formed regardless that the STI structure element isolation regions have a high aspect ratio.

Further, also in the semiconductor storage device and the method of manufacturing the same according to the second embodiment of the present invention, the active element forming regions 3 are formed by epitaxially growing the silicon film on the silicon substrate 1 exposed by the anisotropic etching. Thus, the surface orientation (111) appears on the surface of the silicon film that forms the active element forming regions 3.

Therefore, it can be easily discriminated whether or not the structure of a semiconductor device is the same as the structure according to the semiconductor storage device and the method of manufacturing the same according to the second embodiment of the present invention.

Further, in the structure of the semiconductor storage device and the method of manufacturing the same according to the second embodiment of the present invention, the spaces between the STI element isolation regions 2 are more increased than the first embodiment of the present invention, in addition to that the surface of a silicon film that forms active element forming regions 3 has a chevron-like shape with a surface orientation (111), thereby the surface area of the active element forming regions 3 is more increased than the first embodiment.

Accordingly, a gate width W, which corresponds to the surface portion of the active element forming region 3 in a cross section perpendicular to a bit line shown in FIG. 7A is further increased, thereby the amount of drive current of an element can be further increased than the structure of the first embodiment of the present invention.

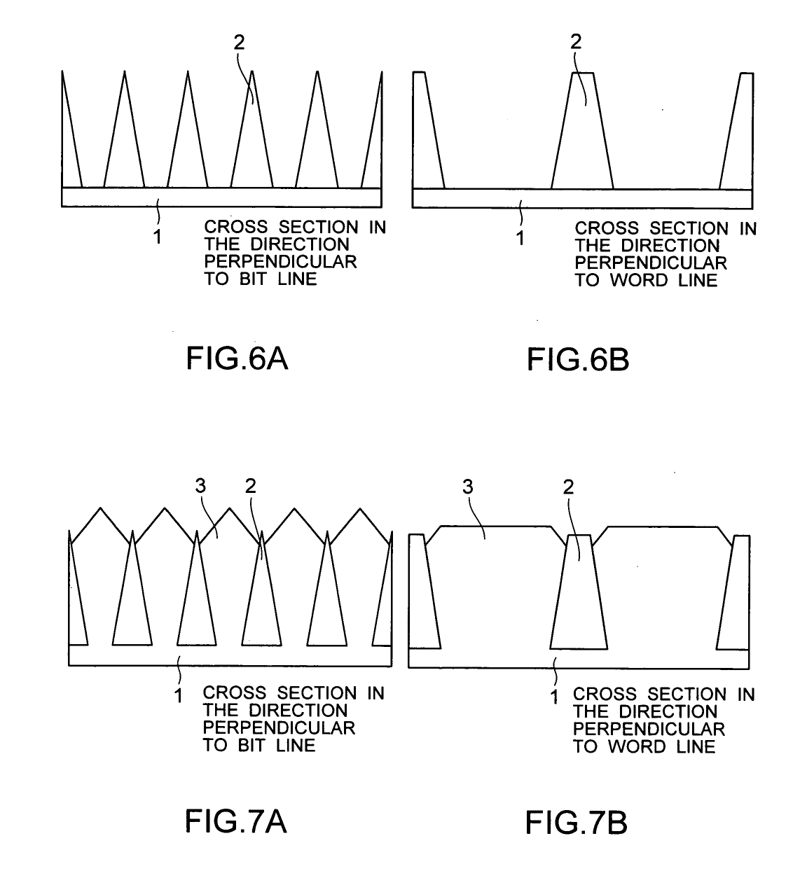

FIG. 8 is a sectional view showing the sectional structure in a direction perpendicular to a bit line of the semiconductor storage device according to a third embodiment of the present invention.

The semiconductor storage device according to the third embodiment of the present invention has a MOSFET structure having a gate insulation films 6 and a gate electrode 7 additionally formed on the structure of the semiconductor storage device according to the first embodiment of the present invention described above.

More specifically, the semiconductor storage device according to the third embodiment of the present invention comprises a silicon substrate 1, element isolation regions 2 formed by processing an insulation film deposited on the silicon substrate 1, active element forming regions 3 composed of a silicon film having a thickness, which is larger than the short side width in the perpendicular cross section thereof as well as smaller than the dimension of the element isolation regions 2 in the depth direction thereof, and having a surface orientation (111) appearing on the upper surface thereof, and formed between one element isolation region 2 and the other element isolation region 2, the gate insulation films 6 formed on the active element forming regions 3, and the gate electrode 7 formed on the gate insulation films 6.

When a voltage is applied to the gate electrode 7, channels 8 are formed, and a MOSFET is placed in a conductive state.

Since the chevron-like portion on the upper surface of the silicon film that acts as the active element forming regions 3 has a shape on which the surface orientation (111) appears, it has a polyhedral shape, that is, a facet shape, thereby the surface area of the active element forming regions 3 is increased than the conventional structure.

Accordingly, a gate width W, which corresponds to the surface portion of the active element forming region 3 in a cross section perpendicular to a bit line shown in FIG. 8 is increased, thereby the amount of drive current of the MOSFET can be increased than the conventional structure.

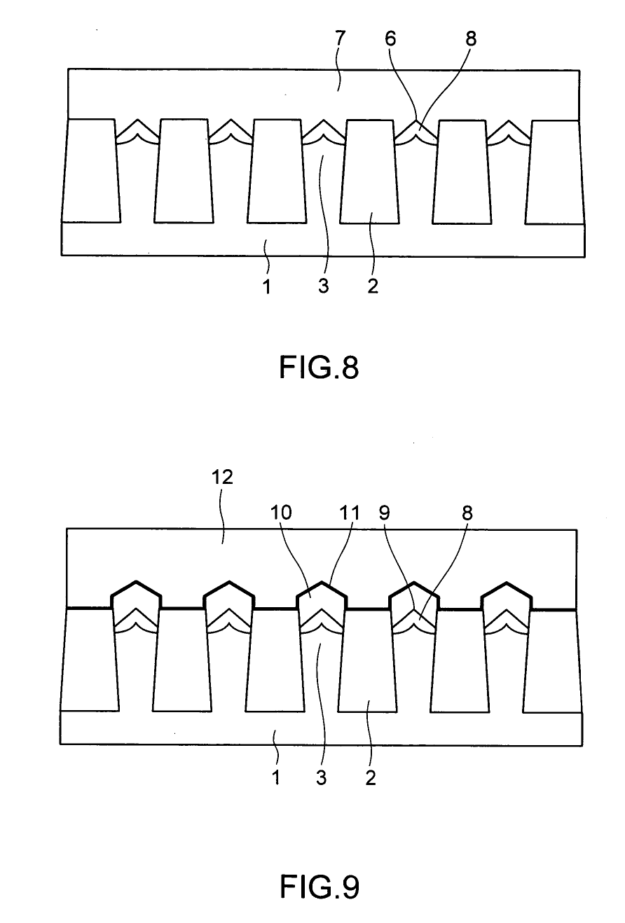

FIG. 9 is a sectional view showing the sectional structure in a direction perpendicular to a bit line of the semiconductor storage device according to a fourth embodiment of the present invention.

The semiconductor storage device according to the fourth embodiment of the present invention has a memory structure of an EPROM, an EEPROM, and the like to which formed are tunnel insulation films 9 formed on active element forming regions 3, floating gates (FG) 10 formed on the tunnel insulation films 9, double-gate interlayer insulation films 11 formed on the floating gates 10, and a control gate (CG) 12 formed on the double-gate interlayer insulation films 11, in addition to the structure of the semiconductor storage device according to the first embodiment of the present invention described above. A logic circuit, for example, a NAND logic circuit and the like can be configurated using the semiconductor storage device according to the fourth embodiment of the present invention.

When a voltage is applied to the control gate 12, channels 8 are formed, thereby the floating gates 10 are placed in a state in which electrons are free to enter and exit them.

Since the chevron-like portion on the upper surface of the silicon film that acts as the active element forming regions 3 has a shape on which the surface orientation (111) appears, it has a polyhedral shape, that is, a facet shape, thereby the surface area of the active element forming regions 3 is increased than the conventional structure.

Accordingly, a gate width W, which corresponds to the surface portion of the active element forming region 3 in a cross section perpendicular to a bit line shown in FIG. 9 is increased, thereby the amount of drive current of the memory such as an EPROM, an EEPROM, and the like can be increased than the conventional structure.

In the manufacturing steps of the semiconductor storage device according to the fourth embodiment of the present invention, the floating gates (FG) 10 must be formed after the active element forming regions 3 are formed as a matter of convenience of the step of forming the active element forming regions 3. That is, a so-called “forming-gate-afterward” process must be employed.

Although the semiconductor storage device is described as an example of the semiconductor device in the above embodiments, the present invention can be applied to any type of semiconductor devices such as a logic semiconductor device and the like.

With the above arrangements, the semiconductor storage device and the method of manufacturing the same according to an aspect of the present invention can provide a semiconductor storage device arranged such that high quality and high reliability can be secured even if STI structure element isolation regions have a high aspect ratio, and a method of manufacturing the same.

What is claimed is:

1. A semiconductor device comprising:
a silicon substrate;
element isolation regions formed by processing an insulation film deposited on the silicon substrate; and
active element forming regions composed of a silicon film having a thickness, which is larger than the short side width in the perpendicular cross section thereof as well as smaller than the dimension of the element isolation regions in the depth direction thereof, and having a surface orientation (111) appearing on the upper surface thereof, and formed between one element isolation region and the other element isolation region.

2. The semiconductor device according to claim 1, wherein the upper surface portion of the active element forming regions has a polyhedral shape.

3. The semiconductor device according to claim 1, wherein the element isolation regions have a forward taper shape.

4. The semiconductor device according to claim 1, further comprising
gate insulation films formed on the active element forming regions; and
a gate electrode formed on the gate insulation films.

5. The semiconductor device according to claim 4 having a MOSFET structure.

6. The semiconductor device according to claim 4, wherein the upper surface portion of the active element forming regions has a polyhedral shape.

7. The semiconductor device according to claim 4, wherein the element isolation regions have a forward taper shape.

8. The semiconductor device according to claim 1 further comprising:
tunnel insulation films formed on the active element forming regions;
floating gates formed on the tunnel insulation films;
double-gate interlayer insulation films formed on the floating gates; and
a control gate formed on the double-gate interlayer insulation films.

9. The semiconductor device according to claim 8 having a memory structure.

10. The semiconductor device according to claim 8, wherein the upper surface portion of the active element forming regions has a polyhedral shape.

11. The semiconductor device according to claim 8, wherein the element isolation regions have a forward taper shape.

12. A method of manufacturing a semiconductor device comprising:
depositing an insulation film on a silicon substrate;
forming element isolation regions by processing the insulation film as well as exposing the surface of the silicon substrate in the region thereof acting as active element forming regions later; and
forming the active element forming regions by epitaxially growing a silicon film on the exposed surface of the silicon substrate such that the thickness thereof is larger than the short side width in the perpendicular cross section thereof as well as smaller than the dimension of the element isolation regions in the depth direction thereof.

13. The method of manufacturing a semiconductor device according to claim 12, wherein a surface orientation (111) appears on the upper surface of the active element forming regions.

14. The method of manufacturing a semiconductor device according to claim 12, wherein the upper surface portion of the active element forming regions has a polyhedral shape.

15. The method of manufacturing a semiconductor device according to claim 12, wherein when the element isolation regions are formed by processing the insulation film, the insulation film is processed to a forward taper shape.

16. The method of manufacturing a semiconductor device according to claim 12, further comprising:
forming gate insulation films on the active element forming regions; and
forming a gate electrode on the gate insulation films.

17. The method of manufacturing semiconductor device according to claim 16, wherein the manufactured semiconductor device has a MOSFET structure.

18. The method of manufacturing a semiconductor device according to claim 12, further comprising:
forming tunnel insulation films on the active element forming regions;
forming floating gates on the tunnel insulation films;
forming double-gate interlayer insulation films on the floating gates; and
forming a control gate on the double-gate interlayer insulation films.

19. The method of manufacturing semiconductor device according to claim 18, wherein the manufactured semiconductor device has a memory structure.
